(19) United States
(12) Patent Application Publication
(10) Pub. No.: US 2004/0022960 A1
(43) Pub. Date: Feb. 5, 2004

(54) Method for preparing dielectric films at a low temperature

(76) Inventors: Shi-Woo Rhee, Pohang-si (KR); Chung Yi, Pohang-si (KR)

Correspondence Address: David A. Einhorn, Esq., Anderson Kill & Olick, P.C., 1251 Avenue of the Americas, New York, NY, 10020, US

(21) Appl. No.: 10/423,338

(22) Filed: Apr. 25, 2003

(30) Foreign Application Priority Data
Apr. 25, 2002 (KR) 2002-0022640

(51) Int. Cl. B05D 3/14; H05H 1/24; H01L 21/84; H01L 21/31; H01L 21/469; H01L 21/00

(52) U.S. Cl. 427/563; 427/579; 438/149; 438/789

(57) ABSTRACT

A dielectric film is prepared by a process comprising a) forming a film on a substrate by depositing a reactant gas containing a precursor of the dielectric film using plasma; b) stopping the reactant gas supply and continuing the plasma treatment to form a dielectric layer from the precursor film; and repeating the steps of a) and b) until a desired thickness of the film is obtained.

### FIELD OF THE INVENTION

The present invention relates to a low-temperature chemical vapor deposition method for preparing a dielectric film on a substrate such as plastics.

### BACKGROUND OF THE INVENTION

A device for flat panel display such as thin film transistor (TFT) is fabricated by depositing a dielectric film on a substrate and forming thereon metallic electrodes and circuits and channel layers.

Glass and silicone have been widely used as a substrate material, and a plastic substrate is considered to be attractive in certain applications. However, plastic substrates cannot be subjected to the traditional thin film deposition processes conducted at a temperature of 140° C. or higher, and therefore, it is required to develop a film deposition process which can be conducted at a temperature as low as about 100° C. when a plastic substrate is to be successfully used in commercial scale.

A low temperature deposition process which uses an extremely diluted reactant gas has been developed, but the qualities of the film produced thereby are not satisfactory in terms of impurity content and density of the film.

Accordingly, the present inventors have endeavored to develop a process for fabricating a film having improved qualities at a lower temperature using CVD process.

### SUMMARY OF THE INVENTION

It is, therefore, an object of the present invention to provide a process for fabricating a film having a low impurity content and high density which can be conducted at a temperature of 100° C. or less.

In accordance with the present invention, there is provided a process for preparing a dielectric film which comprises a) forming a film on a substrate by depositing a reactant gas containing a precursor of the dielectric film using plasma; b) stopping the reactant gas supply and continuing the plasma treatment to form a dielectric layer from the precursor film; and repeating the steps of a) and b) until a desired thickness of the film is obtained.

### BRIEF DESCRIPTION OF THE DRAWINGS

The above and other objects and features of the present invention will become apparent from the following description of the invention, when taken in conjunction with the accompanying drawings which respectively show:

FIG. 1: a schematic diagram of process conditions in accordance with a preferred embodiment of the present invention;

FIG. 2: changes in the secondary ion mass spectroscopy (SIMS) intensities of hydrogen and carbon of the films obtained in Examples and Comparative Examples as function of depositing temperature; and

FIG. 3: changes in the normalized capacitance of the films obtained in Example 1 and Comparative Example 1 as function of gate voltage.

### DETAILED DESCRIPTION OF THE INVENTION

The present invention provides a process for preparing a dielectric film having a good quality by way of plasma treating a dielectric layer formed by CVD at a low temperature in the absence of reactant gas. Such plasma treatment removes impurities from the film and increases the film density.

In accordance with a preferred embodiment of the present invention, the plasma power used in step a) is higher than that of step b). Specifically, it is preferable that plasma energies of steps a) and b) are 60˜100 W and 20˜60 W, respectively.

In accordance with another preferred embodiment of the present invention, in the step b), the reactant gas may be purged after stopping the reactant gas supply.

Preferably, step a) is conducted at a temperature of room temperature to 100° C., and the thickness of the dielectric film deposited in step a) is 3˜12 nm.

The dielectric precursor may be preferably selected from the group consisting of tetraethylorthosilicate (TEOS), tetramethylorthosilicate (TMOS), tetrapropylorthosilicate (TPOS) and tetrabuthylorthosilicate (TBOS).

In accordance with a preferred embodiment of the present invention, the plasma may be excited by oxygen or an oxygen-containing gas selected from the group consisting of oxygen/helium, oxygen/argon and oxygen/nitrogen.

In practice, the process for forming a dielectric film may be conducted using a plasma CVD technique, e.g., a direct plasma CVD or a remote plasma CVD technique. The remote plasma CVD technique is more preferable since it is easier to control vapor phase chemical species formed by decomposition of the reactant gas in the plasma.

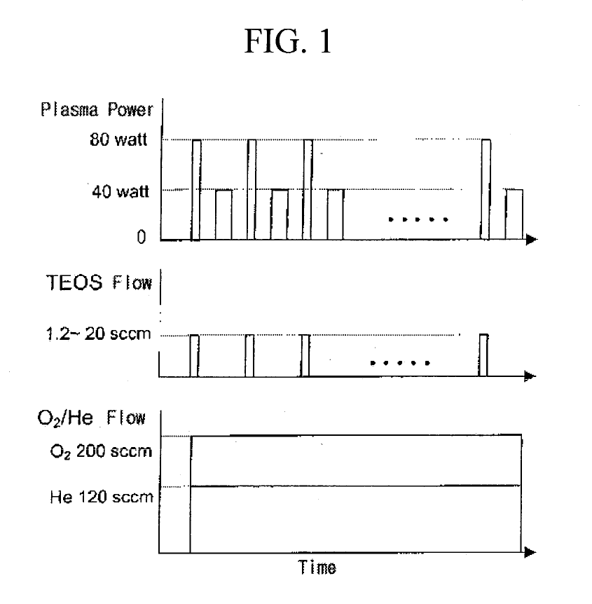

FIG. 1 depicts process conditions, i.e., plasma power and flow rates of reactant and plasma exciting gas in accordance with a preferred embodiment of the present invention. In the example, the reactant, e.g. tetraethylorthosilicate (TEOS), is supplied to a plasma chamber at a flow rate of 1.2˜20 sccm and deposited on a substrate with 80W of plasma power to form a silicone oxide film.

The deposition may be conducted at a temperature ranging from room temperature to 100° C., and therefore, a plastic substrate may be used. Then, the reactant gas is purged from the chamber and the film formed on the substrate is treated with 40W of plasma power using oxygen/helium gas. The period for plasma treatment may be varied depending on deposition conditions, from about 1 second to about 10 minutes. Plasma treating is conducted so as to remove impurities from the film and increase the film density. Oxygen plasma treatment and deposition of TEOS are repeated to obtain a dielectric film of a desired thickness.

The present invention is further described and illustrated in the following Examples, which are, however, not intended to limit the scope of the present invention.

### EXAMPLE 1

A silicone oxide film was deposited on a flexible plastic substrate (polyethyleneterephthalate: PET) using TEOS and oxygen/helium in a plasma chemical vapor deposition apparatus (RF Plasma ST-350 of Autoelectronic Inc.).

The flow rates of TEOS, oxygen and helium were 1.2, 200 and 120 sccm, respectively. The chamber was kept at 1 torr and 50° C., and the applied plasma power was 80 W. The thickness of the film so deposited was 6 nm. Then, the TEOS supply was stopped and the chamber was purged for 1 minute. The film was treated with oxygen plasma for 1 minute at a plasma power of 40 W. When the first plasma treatment was completed, the TEOS supply was resumed and a silicone oxide film of 6 nm was additionally deposited at 80 W plasma power. Such deposition and plasma treatment was repeated 5 to 50 times to obtain a dielectric film of 100 nm.

### EXAMPLES 2 TO 5

The procedure of Example 1 was repeated 4 times at deposition temperatures of 100, 150, 200 and 250° C., respectively.

### COMPARATIVE EXAMPLES 1 TO 5

The procedures of Examples 1 to 5 were repeated except that silicone oxide dielectric films having a thickness of 100 nm were prepared without oxygen plasma treatment.

(1) SIMS analysis for carbon and hydrogen contents

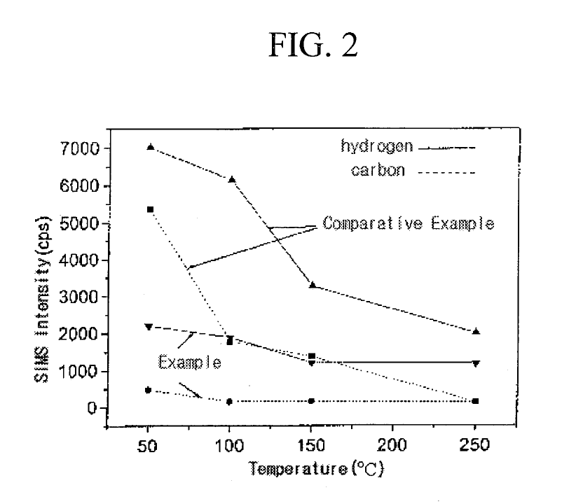

FIG. 2 exhibits carbon and hydrogen contents of the dielectric films obtained in Examples and Comparative Examples determined by SIMS analysis (cameca TMS-6f). As shown in FIG. 2, as the deposition temperature decreases, the carbon and hydrogen contents in the film increase, but the films obtained in Examples 1 to 5 show much lower carbon and hydrogen contents than those of Comparative Examples 1 to 5.

(2) Electric properties

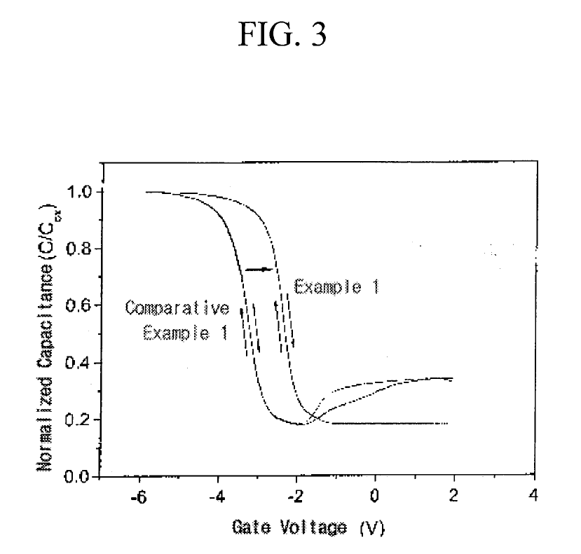

FIG. 3 shows capacitance-voltage properties of the films obtained in Example 1 and Comparative example 1 (determined by HP 4275 multi-frequency LCR meter). Hysteresis and capacitance distortion were not observed for the film obtained in Example 1 showing that the electric property of the film is improved by periodic oxygen plasma treatment. Further, it is noted that the capacitance curve for the film of Example 1 has shifted toward positive suggesting that the amount of positive charged impurities in the film is low.

As can be seen from the above result, the dielectric film prepared by conducting periodic oxygen plasma treatment of dielectric film deposited at a low temperature, shows improved electric properties and the impurities contents in the film is extremely low, and therefore, it can be successfully used as a dielectric film for a gate. According to the present invention, it is possible a high quality dielectric film on a substrate having a low heat resistance such as plastics.

While some of the preferred embodiments of the subject invention have been described and illustrated, various changes and modifications can be made therein without departing from the spirit of the present invention defined in the appended claims.

What is claimed is:

1. A process for preparing a dielectric film which comprises a) forming a film on a substrate by depositing a reactant gas containing a precursor of the dielectric film using plasma; b) stopping the reactant gas supply and continuing the plasma treatment to form a dielectric layer from the precursor film; and repeating the steps of a) and b) until a desired thickness of the film is obtained.

2. The process of claim 1, wherein the plasma power of step a) is higher than that of step b).

3. The process of claim 1, wherein the plasma powers of steps a) and b) are 60˜100 W and 20˜60 W, respectively.

4. The process of claim 1, wherein step b) further comprises step of purging the reactant gas after stopping the reactant gas supply.

5. The process of claim 1, wherein step a) is conducted at a temperature in the range of room temperature to 100° C.

6. The process of claim 1, wherein the precursor is selected from the group consisting of tetraethylorthosilicate (TEOS), tetramethylorthosilicate (TMOS), tetrapropylorthosilicate (TPOS) and tetrabuthylorthosilicate (TBOS).

7. The process of claim 1, wherein the thickness of the dielectric film deposited in step a) is 3˜12 nm.

8. The process of claim 1, wherein the substrate is a plastic substrate.

9. The process of claim 1, wherein the plasma is excited by oxygen or an oxygen containing gas.

10. The process of claim 9, wherein the oxygen containing gas is selected from the group consisting of oxygen/helium, oxygen/argon and oxygen/nitrogen.
